(19) United States
(12) Patent Application Publication
(10) Pub. No.: US 2026/0129846 A1
(43) Pub. Date: May 7, 2026

(54) SEMICONDUCTOR DEVICE

(71) Applicant: Samsung Electronics Co., Ltd., Suwon-si (KR)

(72) Inventors: Eunshoo HAN, Suwon-si (KR); Byeung Chul KIM, Suwon-si (KR)

(73) Assignee: Samsung Electronics Co., Ltd., Suwon-si (KR)

(21) Appl. No.: 19/180,350

(22) Filed: Apr. 16, 2025

(30) Foreign Application Priority Data
Nov. 6, 2024 (KR) 10-2024-0156448

(51) Int. Cl. H10B 12/00

(52) U.S. Cl. CPC H10B 12/50; H10B 12/315; H10B 12/34

(57) ABSTRACT

A semiconductor device may include a substrate including a cell array region and a peripheral circuit region, an active region in the cell array region, word lines intersecting and overlapping the active region and extending in a first direction to the peripheral circuit region, and pads in the peripheral circuit region and overlapping corresponding ones of the word lines, respectively. In the peripheral circuit region on a side of the cell array region, each of the pads is configured to be shifted in a direction towards one of the word lines, which is adjacent thereto and closest to the cell array region from among the word lines, relative to a center of a word line that overlaps the pad in a plan view.

### CROSS-REFERENCE TO RELATED APPLICATION

This application claims priority to and the benefit of Korean Patent Application No. 10-2024-0156448 filed at the Korean Intellectual Property Office on Nov. 6, 2024, the entire contents of which are incorporated herein by reference.

### BACKGROUND

### Field

The present disclosure relates to a semiconductor devices.

### Description of the Related Art

A buried channel array transistor (BCAT) that buries a gate electrode inside a semiconductor substrate and reduces or minimizes a portion where gate and drain regions overlap has been proposed to reduce undesirable effects (e.g., a leakage current) caused by a shortened channel length as semiconductor devices become more highly integrated.

### SUMMARY

Some example embodiments of the present disclosure provide semiconductor devices that reduce or prevent a short circuit of a pad and/or secures a margin of a disposition of the pad.

A semiconductor device according to an example embodiment of the present disclosure includes a substrate including a cell array region and a peripheral circuit region surrounding the cell array region, an active region in the cell array region, a plurality of word lines intersecting and overlapping the active region, the plurality of word lines extending in a first direction to the peripheral circuit region, a plurality of bit lines intersecting the active region and the plurality of word lines, the plurality of bit lines extending in a second direction intersecting the first direction, and a plurality of pads in the peripheral circuit region and overlapping corresponding ones of the plurality of word lines, respectively. In the peripheral circuit region on a first side of the cell array region, the plurality of word lines include a first word line, a second word line, a third word line, and a fourth word line, an end portion of at least one of the first word line, the second word line, the third word line, and the fourth word line does not coincide with an end portion of another word line of the first word line, the second word line, the third word line, and the fourth word line, an end portion of the second word line is farthest from the cell array region and an end portion of the fourth word line is closest to the cell array region, and from among the plurality of pads, a first pad overlapping the first word line is configured to be shifted in a direction towards the fourth word line adjacent thereto relative to a center of the first word line and a third pad overlapping the third word line is configured to be shifted in a direction towards the fourth word line adjacent thereto relative to a center of the third word line.

A semiconductor device according to another example embodiment includes a substrate including a cell array region and a peripheral circuit region surrounding the cell array region, an active region in the cell array region, a plurality of word lines intersecting and overlapping the active region, the plurality of word lines extending in a first direction to the peripheral circuit region, a plurality of bit lines intersecting the active region and the word line, the plurality of bit lines extending in a second direction intersecting the first direction, and a plurality of pads in the peripheral circuit region and overlapping corresponding ones of the plurality of word lines, respectively. End portions of two or more of the plurality of word lines in the peripheral circuit region protrude in the first direction to different degrees, and distances in the second direction between adjacent pairs of the plurality of pads in the peripheral circuit region are different.

A semiconductor device according to another example embodiment includes a substrate including a cell array region and a peripheral circuit region surrounding the cell array region, an active region in the cell array region, a plurality of word lines intersecting and overlapping the active region, the plurality of word lines extending in a first direction to the peripheral circuit region, a plurality of bit lines intersecting the active region and the word line, the plurality of bit lines extending in a second direction intersecting the first direction, and a plurality of pads in the peripheral circuit region and overlapping corresponding ones of the plurality of word lines. End portions of two or more of the plurality of word lines in the peripheral circuit region protrude in the first direction to different degrees, and a center of a word line of the plurality of word lines does not coincide with a center of a pad of the plurality of pads overlapping the word line.

A method of manufacturing a semiconductor device according to an example embodiment includes comprising forming a plurality of dummy patterns on a substrate, the plurality of dummy patterns extending in a first horizontal direction and arranged in a second direction crossing the first horizontal direction, forming a pattern along a circumferences of each of the plurality of dummy patterns, removing the plurality of dummy patterns, forming a spacer along each of an inner side surface and an outer side surface of the pattern, removing edges of the pattern and the spacer in a peripheral circuit region of the substrate to form isolated sub-patterns and isolated spacer patterns, respectively, wherein the spacer includes a plurality of spacers and the isolation pattern has a wave shape with a period that overlaps a group of four adjacent ones from among the plurality of spacers, removing the pattern, etching a substrate at regions where the isolated spacer pattens are located to form a plurality of word line trenches, filling the plurality of word line trenches to form a plurality of word lines, and forming a plurality of pads to overlap such that each of the plurality of pads corresponds one word line from among the plurality of word lines and is shifted in a direction towards an adjacent word line with a shortest length from among the plurality of word lines.

According to some example embodiments, semiconductor devices that reduce or prevent a short circuit of a pad and/or secures a margin of a disposition of the pad (or pads) is provided.

### BRIEF DESCRIPTION OF THE DRAWINGS

FIG. 1 is a plan view showing a semiconductor device according to an example embodiment.

FIG. 2 is a cross-sectional view cut along a line A-A′ of FIG. 1.

FIG. 3 is a cross-sectional view cut along a line B-B′ of FIG. 1.

FIG. 4 is a cross-sectional view cut along a line C-C′ of FIG. 1.

Each of FIG. 5 and FIG. 6 schematically illustrates a disposition of a word line and a disposition of a pad at a peripheral circuit region.

FIG. 7 shows the same region as that of FIG. 6 according to another example embodiment.

FIG. 8 shows the same region as that of FIG. 6 according to another example embodiment.

FIGS. 9 to 22 illustrate a manufacturing method according to an example embodiment.

### DETAILED DESCRIPTION

Some example Embodiments of the present disclosure will be described more fully hereinafter with reference to the accompanying drawings so that those skilled in the art could easily implement the example embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and example embodiments of the present disclosure are not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

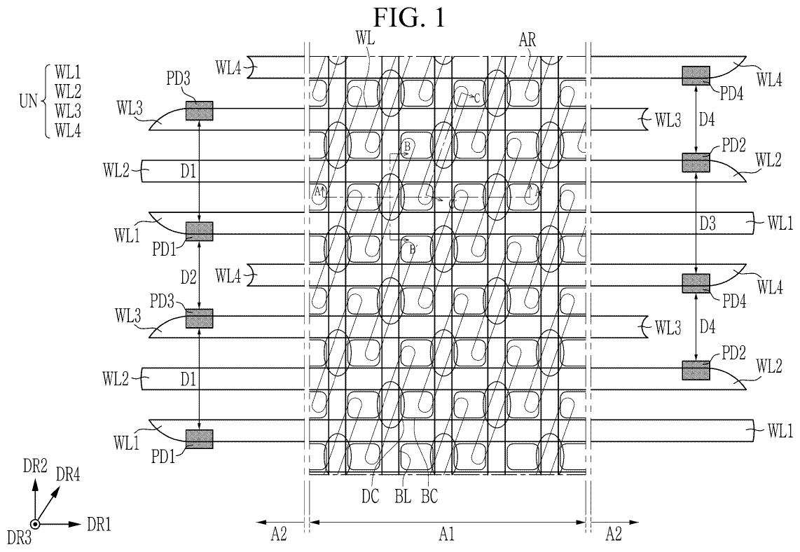

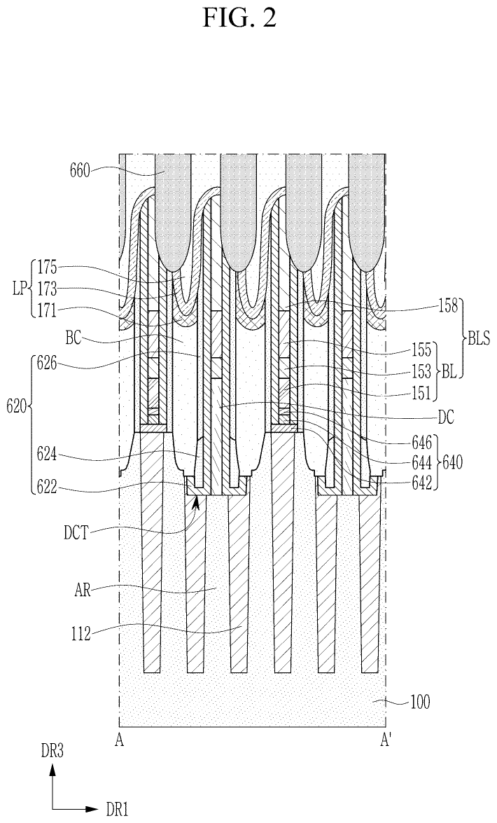

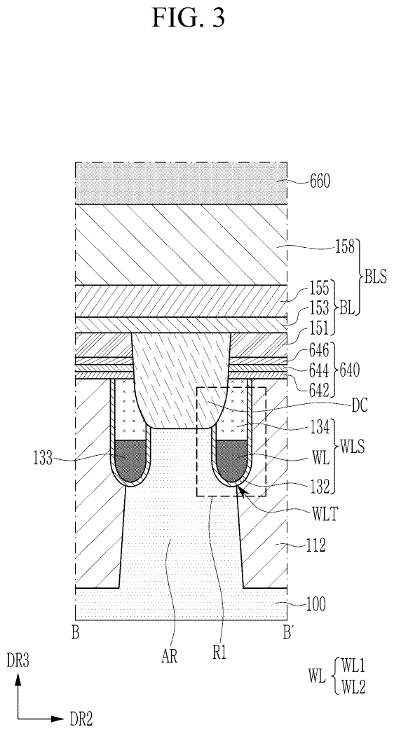

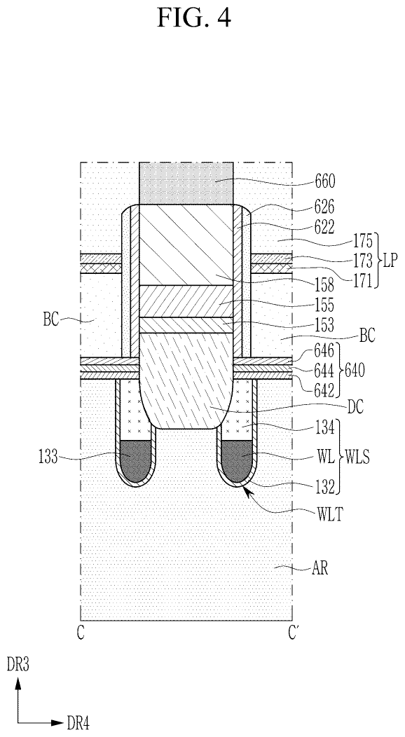

FIG. 1 is a plan view showing a semiconductor device according to an example embodiment. FIG. 2 is a cross-sectional view cut along a line A-A′ of FIG. 1. FIG. 3 is a cross-sectional view cut along a line B-B′ of FIG. 1. FIG. 4 is a cross-sectional view cut along a line C-C′ of FIG. 1.

Referring to FIG. 1, the semiconductor device according to the present example embodiment may include a cell array region A1 and a peripheral circuit region A2. The cell array region A1 may be a region where a plurality of memory cells are formed, and a plurality of active regions AR may be disposed at the cell array region. The peripheral circuit region A2 may be disposed to surround the cell array region, and elements that drive the memory cells may be disposed at the peripheral circuit region A2.

The present example embodiment may relate to a shape of a word line WL and a disposition of a pad PD in the peripheral circuit region A2 to secure a margin of a disposition of the pad PD by forming the word lines WL to have different lengths in the peripheral circuit region A2. A detailed disposition of the peripheral circuit region A2 will be separately described later.

First, the cell array region A1 will be described. As shown in FIGS. 1 to 4, the semiconductor device according to the example embodiment may include the active region AR, and the word line WL and a bit line BL intersecting and overlapping the active region AR.

The active region AR may be defined by an element isolation layer 112 disposed within a substrate 100. The plurality of active regions AR may be disposed within the substrate 100, and may be isolated (or separated) from each other by the element isolation layer 112. The element isolation layer 112 may be disposed at both sides of each active region AR.

The substrate 100 may include a semiconductor material. For example, the substrate 100 may include a Group IV semiconductor, a Group III-V compound semiconductor, a Group II-VI compound semiconductor, or the like. For example, the substrate 100 may include a semiconductor such as Si or Ge, or a compound semiconductor such as SiGe, SiC, GaAs, InAs, or InP. However, a material of the substrate 100 is not limited thereto, and may be variously changed.

The substrate 100 may have an upper surface parallel to a first direction DR1 and a second direction DR2, and may have a thickness parallel to a third direction DR3 perpendicular to the first direction DR1 and the second direction DR2.

The active region AR may have a rod shape extending along a fourth direction DR4 oblique to the first direction DR1 and the second direction DR2. The fourth direction DR4 may be parallel to an upper surface of the substrate 100, and may be disposed on the same plane as those of the first direction DR1 and the second direction DR2. The fourth direction DR4 may form an acute angle with each of the first direction DR1 and the second direction DR2.

The plurality of active regions AR may extend in a direction parallel to each other. The plurality of active regions AR may be disposed to be spaced apart from each other by a desired (or alternatively, predetermined) interval along the fourth direction DR4 and the first direction DR1. A central portion of one active region AR may be adjacent to an end portion of the other active region AR in the first direction DR1. One end portion of one active region AR may be adjacent to the other end portion of the other active region AR in the first direction DR1. However, a shape or a disposition form of the active region AR is not limited thereto, and may be variously changed.

The element isolation layer 112 may have a shallow trench isolation (STI) structure that exhibits a relatively good element isolation characteristic. The element isolation layer 112 may be formed of or include silicon oxide, silicon nitride, or a combination thereof. However, a material of the element isolation layer 112 is not limited thereto, and may be variously changed.

The element isolation layer 112 may be formed of a single layer or multiple layers. The element isolation layer 112 may be formed of a single material, or may include two or more types of insulating materials.

The word line WL may extend along the first direction DR1, and may intersect the active region AR. The word line WL may overlap the active region AR, and may serve as a gate electrode. One word line WL may overlap the plurality of active regions AR adjacent to each other along the first direction DR1. A plurality of word lines WL may extend parallel to each other along the first direction DR1, and may be spaced apart from each other at regular intervals along the second direction DR2.

Each of the plurality of active regions AR may intersect and overlap two word lines WL. Each active region AR may be divided into three portions by the two word lines WL. In this case, a central portion of the active region AR disposed between the two word lines WL may be a portion connected to the bit line BL, and both end portions of the active region AR disposed outside the two word lines WL each may be a portion connected to a capacitor (not shown). The bit line BL may be connected to the active region AR through a direct contact DC. The capacitor may be connected to the active region AR through a landing pad LP and a buried contact BC.

A word line trench WLT may be formed at the substrate 100, and a word line structure WLS may be disposed within the word line trench WLT. That is, the word line structure WLS may have a form buried within the substrate 100. A portion of the word line trench WLT may be disposed on the active region AR, and another portion of the word line trench WLT may be disposed on the element isolation layer 112.

The word line structure WLS may include a gate insulating layer 132, the word line WL disposed on the gate insulating layer 132, and a word line capping layer 134 disposed on the word line WL. However, a position, a shape, a structure, or the like of the word line structure WLS is not limited thereto, and may be variously changed.

The gate insulating layer 132 may be disposed within the word line trench WLT. The gate insulating layer 132 may be conformally formed on an inner wall surface of the word line trench WLT. The gate insulating layer 132 may include silicon oxide, silicon nitride, silicon oxynitride, a high dielectric constant (high-k) material having a dielectric constant higher than that of the silicon oxide, or a combination thereof. However, a position, a shape, a material, or the like of the gate insulating layer 132 is not limited thereto, and may be variously changed.

The word line WL may be disposed on the gate insulating layer 132. A side surface and a bottom surface of the word line WL may be surrounded by the gate insulating layer 132. The gate insulating layer 132 may be disposed between the word line WL and the active region AR. Therefore, the word line WL may not be in direct contact with the active region AR.

The word line WL may include Ti, TiN, Ta, TaN, W, WN, TiSiN, WSiN, polysilicon, or a combination thereof. However, a position, a shape, a material, or the like of the word line WL is not limited thereto, and may be variously changed.

The word line capping layer 134 may be disposed on the word line WL. The word line capping layer 134 may entirely cover an upper surface of the word line WL. A lower surface of the word line capping layer 134 may be in contact with the word line WL. A side surface of the word line capping layer 134 may be covered by the gate insulating layer 132. The word line capping layer 134 may include silicon oxide, silicon nitride, silicon oxynitride, or a combination thereof. However, a position, a shape, a material, or the like of the word line capping layer 134 is not limited thereto, and may be variously changed.

The word line WL may be disposed at both sides of the direct contact DC, and at least a portion of the word line WL may overlap the direct contact DC in the third direction DR3. An upper surface of the word line WL may be disposed at a lower level than that of a lower surface of the direct contact DC. The word line capping layer 134 may be disposed between the word line WL and the direct contact DC. Therefore, the word line WL and the direct contact DC may be insulated from each other by the word line capping layer 134. However, a positional relationship between the word line WL and the direct contact DC is not limited thereto, and may be variously changed.

The bit line BL may extend along the second direction DR2, and may intersect the active region AR and the word line WL. In this case, the bit line BL may vertically intersect the word line WL. The bit line BL may be disposed above the word line WL.

One bit line BL may overlap the plurality of active regions AR adjacent to each other along the second direction DR2. The bit line BL may be connected to the active region AR through the direct contact DC. One bit line BL may be connected to the plurality of active regions AR adjacent to each other along the second direction DR2. Each of the plurality of active regions AR may be connected to one bit line BL. A central portion of the active region AR may be connected to the bit line BL. However, this is only one example, and a connection form between the bit line BL and the active region AR may be variously changed.

A plurality of bit lines BL may extend parallel to each other along the second direction DR2, and may be spaced apart from each other at regular intervals along the first direction DR1.

A direct contact trench DCT may be formed at the substrate 100, and the direct contact DC may be disposed within the direct contact trench DCT. The direct contact trench DCT may be disposed on the active region AR, and the direct contact DC may be connected to the active region AR. The direct contact DC may be directly connected to the active region AR. The direct contact DC may overlap the active region AR in the third direction DR3. The direct contact DC may include a conductive material. For example, the direct contact DC may include polysilicon doped with an impurity, or metal such as W, Mo, Au, Cu, Al, Ni, or Co.

The bit line BL may be disposed above or on the substrate 100 and the direct contact DC. The bit line BL may include a first conductive layer 151, a second conductive layer 153, and a third conductive layer 155 that are sequentially stacked.

Each of the first conductive layer 151, the second conductive layer 153, and the third conductive layer 155 may include a conductive material. For example, the first conductive layer 151 may include polysilicon doped with an impurity, or metal such as W, Mo, Au, Cu, Al, Ni, or Co. The second conductive layer 153 may include metal such as Ti or Ta and/or metal nitride such as TiN or TaN. The third conductive layer 155 may include metal such as W, Mo, Au, Cu, Al, Ni, or Co. However, a structure, material, and the like of each of the conductive layers constituting the bit line BL are not limited thereto, and may be variously changed.

The bit line BL may be in direct contact with the direct contact DC. The first conductive layer 151 of the bit line BL may be in contact with a side surface of the direct contact DC, and the second conductive layer 153 of the bit line BL may be in contact with an upper surface of the direct contact DC. The direct contact DC may be disposed between the active region AR and the bit line BL, and may electrically connect the active region AR and the bit line BL. That is, the bit line BL may be connected to the active region AR through the direct contact DC.

The first conductive layer 151 among the conductive layers constituting the bit line BL and the direct contact DC may include the same material. For example, each of the first conductive layer 151 and the direct contact DC may include polysilicon doped with an impurity. However, example embodiments of the present disclosure are not limited thereto, and the first conductive layer 151 and the direct contact DC may include different materials.

A bit line capping layer 158 may be disposed on the bit line BL. The bit line BL and the bit line capping layer 158 may form a bit line structure BLS. The bit line capping layer 158 may overlap the bit line BL and the direct contact DC in the third direction DR3. The bit line BL and the direct contact DC may be patterned using the bit line capping layer 158 as a mask. A planar shape of the bit line BL may be substantially the same as that of the bit line capping layer 158. The bit line capping layer 158 is shown as being in contact with the third conductive layer 155 of the bit line BL, but example embodiments of the present disclosure are not limited thereto. Another layer may be further disposed between the bit line capping layer 158 and the third conductive layer 155 of the bit line BL.

The bit line capping layer 158 may include silicon nitride. However, a material of the bit line capping layer 158 is not limited thereto, and may be variously changed.

A spacer structure 620 may be disposed at both sides of the bit line structure BLS. The spacer structure 620 may cover side surfaces of the bit line capping layer 158, the bit line BL, and the direct contact DC. The spacer structure 620 may extend approximately in the third direction DR3 along a side surface of the bit line structure BLS. At least a portion of the spacer structure 620 may be disposed within the direct contact trench DCT. The spacer structure 620 may be disposed at both sides of the direct contact DC within the direct contact trench DCT.

The spacer structure 620 may be formed of multiple layers made of a combination of various types of insulating materials.

The spacer structure 620 may include a first spacer 622, a second spacer 624, and a third spacer 626. However, example embodiments of the present disclosure are not limited thereto, and the number and a structure of layers constituting the spacer structure 620 may be variously changed.

Additionally, the spacer structure 620 may be formed as a single layer. In some cases, the spacer structure 620 may be formed as an air spacer structure including an air space surrounded between the spacers.

The first spacer 622 may cover side surfaces of the bit line structure BLS and the direct contact DC. The first spacer 622 may be formed to cover a bottom surface and a side surface of the direct contact trench DCT within the direct contact trench DCT.

The second spacer 624 may be disposed on the first spacer 622. A lower surface and a side surface of the second spacer 624 may be surrounded by the first spacer 622. The second spacer 624 may be disposed within the direct contact trench DCT. The second spacer 624 may be formed to fill the direct contact trench DCT. The second spacer 624 may be disposed at both sides of the direct contact DC within the direct contact trench DCT.

The third spacer 626 may be disposed on the first spacer 622 and the second spacer 624. The third spacer 626 may overlap the first spacer 622 along the first direction DR1, and may overlap the second spacer 624 along the third direction DR3. The third spacer 626 may extend approximately in the third direction DR3 along a side surface of the first spacer 622. The third spacer 626 may extend in parallel with the first spacer 622.

The spacer structure 620 may include an insulating material. The first spacer 622 and the second spacer 624 may include the same material, and the third spacer 626 may include a different material from those of the first spacer 622 and the second spacer 624. In some example embodiments, the first spacer 622, the second spacer 624, and the third spacer 626 may include different materials.

Each of the first spacer 622 and the second spacer 624 may include at least one of silicon nitride, silicon oxynitride, silicon oxide, silicon carbonoxide, silicon carbonitride, silicon oxycarbonitride, or a combination thereof. The third spacer 626 may include at least one of SiOCN, SiOC, SiOCF, or a combination thereof. However, a material of the spacer structure 620 is not limited thereto, and may be variously changed.

An insulating layer 640 may be disposed below the bit line BL. The insulating layer 640 may be disposed between the bit line BL and the element isolation layer 112. The direct contact DC may be disposed between the bit line BL and the active region AR, and the insulating layer 640 may not be disposed between the bit line BL and the active region AR.

The insulating layer 640 may be disposed on the word line structure WLS. The insulating layer 640 may be disposed between the word line structure WLS and the bit line BL. The insulating layer 640 may include a first insulating layer 642, a second insulating layer 644, and a third insulating layer 646 that are sequentially stacked.

At least some of the first insulating layer 642, the second insulating layer 644, and the third insulating layer 646 may have different widths. Widths of the second insulating layer 644 and the third insulating layer 646 may be substantially the same. The widths of the second insulating layer 644 and the third insulating layer 646 may be substantially the same as widths of the bit line BL and the bit line capping layer 158. A width of the first insulating layer 642 may be different from the widths of the second insulating layer 644 and the third insulating layer 646. The width of the first insulating layer 642 may be wider than the widths of the second insulating layer 644 and the third insulating layer 646. Therefore, the width of the first insulating layer 642 may be wider than the width of the bit line BL.

The insulating layer 640 may be covered by the spacer structure 620. For example, an upper surface of the first insulating layer 642 may be covered by the first spacer 622. Side surfaces of the second insulating layer 644 and the third insulating layer 646 may be covered by the first spacer 622.

The insulating layer 640 may include an insulating material. Each of the first insulating layer 642, the second insulating layer 644, and the third insulating layer 646 may include an insulating material. For example, the first insulating layer 642 may include silicon oxide. The second insulating layer 644 may include a material having etch selectivity different from that of the first insulating layer 642. For example, the second insulating layer 644 may include silicon nitride. For example, the third insulating layer 646 may include silicon oxide or silicon nitride. However, a structure, a material, or the like of the insulating layer 640 is not limited thereto, and may be variously changed.

The buried contact BC may be disposed between an adjacent pair of the plurality of bit lines BL. The semiconductor device according to the example embodiment may include a plurality of buried contacts BC. The plurality of buried contacts BC may be disposed to be spaced apart from each other along the first direction DR1 and the second direction DR2. For example, the plurality of buried contacts BC may be disposed to be spaced apart from each other along the second direction DR2 between two adjacent bit lines BL. Additionally, the plurality of buried contacts BC may be disposed to be spaced apart from each other along the first direction DR1 between two adjacent word lines WL. However, a disposition form of the plurality of buried contacts BC is not limited thereto, and may be variously changed.

At least a portion of the buried contact BC may overlap the active region AR in the third direction DR3, and another portion of the buried contact BC may overlap the element isolation layer 112 in the third direction DR3. The buried contact BC may be electrically connected to the active region AR. The buried contact BC may be in direct contact with the active region AR. At least a portion of a lower surface and a side surface of the buried contact BC may be surrounded by the active region AR. However, example embodiments of the present disclosure are not limited thereto, and another layer may be disposed between the buried contact BC and the active region AR, and the buried contact BC may be connected to the active region AR through the another layer.

The buried contact BC may include a conductive material. For example, the buried contact BC may include polysilicon doped with an impurity, but example embodiments of the present disclosure are not limited thereto.

The spacer structure 620 may be disposed on both side surfaces of the buried contact BC. The spacer structure 620 may be disposed between the buried contact BC and the bit line BL. For example, one side surface of the buried contact BC may be in contact with the third spacer 626 and the active region AR, and the other side surface of the buried contact BC may be in contact with the third spacer 626 and the second spacer 624.

A lower surface of the buried contact BC may be in contact with the first spacer 622. However, this is only one example, and a positional relationship between the buried contact BC and the spacer structure 620 may be variously changed.

An upper surface of the buried contact BC may be disposed at a lower level than that of an upper surface of the bit line BL, and the lower surface of the buried contact BC may be disposed at a higher level than that of the lower surface of the direct contact DC. However, example embodiments of the present disclosure are not limited thereto, and a positional relationship between the buried contact BC, the bit line BL, and the direct contact DC may be variously changed.

The landing pad LP may be disposed on the buried contact BC. A plurality of landing pads LP may be disposed to be spaced apart from each other along the first direction DR1 and the second direction DR2. The plurality of landing pads LP may be disposed in a row along the first direction DR1. The plurality of landing pads LP may be disposed in a zigzag shape along the second direction DR2. For example, the plurality of landing pads LP may be alternately disposed at a left side and a right side with respect to the bit line BL along the second direction DR2. However, a disposition form of the plurality of landing pads LP is not limited thereto, and may be variously changed.

The landing pad LP may cover the upper surface of the buried contact BC, and may overlap the buried contact BC in the third direction DR3. At least a portion of the landing pad LP may overlap the spacer structure 620 in the third direction DR3, and may overlap the bit line BL in the third direction DR3. An upper surface of the landing pad LP may be disposed at a level higher than that of an upper surface of the bit line capping layer 158. The spacer structure 620 may be disposed on both side surfaces of the landing pad LP. The spacer structure 620 may be disposed between the landing pad LP and the bit line BL, and between the landing pad LP and the bit line capping layer 158. The landing pad LP may be electrically connected to the buried contact BC. The landing pad LP may be in direct contact with the buried contact BC. The landing pad LP may be electrically connected to the active region AR through the buried contact BC.

The landing pad LP may include a metal silicide layer 171, a conductive barrier layer 173, and a conductive layer 175.

The metal silicide layer 171 may be disposed on the buried contact BC, the conductive barrier layer 173 may be disposed on the metal silicide layer 171, and the conductive layer 175 may be disposed on the conductive barrier layer 173.

The metal silicide layer 171 may be in direct contact with the buried contact BC. The metal silicide layer 171 may entirely cover the upper surface of the buried contact BC. The upper surface of the buried contact BC may have a concave shape, and the metal silicide layer 171 may have a concave shape along the upper surface of the buried contact BC. The spacer structure 620 may be disposed on both side surfaces of the metal silicide layer 171. The metal silicide layer 171 may include a metal silicide material such as cobalt silicide, nickel silicide, or manganese silicide. However, a shape, a material, and the like of the metal silicide layer 171 are not limited thereto, and may be variously changed. In some cases, the metal silicide layer 171 may be omitted.

The conductive barrier layer 173 may be disposed between the metal silicide layer 171 and the conductive layer 175. A lower surface of the conductive barrier layer 173 may be in contact with the metal silicide layer 171. The spacer structure 620 may be disposed on both side surfaces of the conductive barrier layer 173. For example, the conductive barrier layer 173 may cover upper surfaces of the first spacer 622 and the third spacer 626.

The conductive barrier layer 173 may be in contact with the first spacer 622 and the third spacer 626. The conductive barrier layer 173 may include Ti, TiN, or a combination thereof. However, a shape, a material, and the like of the conductive barrier layer 173 are not limited thereto, and may be variously changed.

A lower surface of the conductive layer 175 may be in contact with the conductive barrier layer 173. At least a portion of a lower surface and a side surface of the conductive layer 175 may be surrounded by the conductive barrier layer 173. The conductive barrier layer 173 may be disposed between the conductive layer 175 and the metal silicide layer 171. The conductive barrier layer 173 may be disposed between the conductive layer 175 and the spacer structure 620.

The conductive layer 175 may include metal, metal nitride, polysilicon doped with an impurity, or a combination thereof. For example, the conductive layer 175 may include W. However, a shape, a material, and the like of the conductive layer 175 are not limited thereto, and may be variously changed.

An insulating pattern 660 may be disposed between the plurality of landing pads LP. The insulating pattern 660 may be formed to fill a space between the plurality of landing pads LP. The plurality of landing pads LP may be isolated from each other by the insulating pattern 660.

The insulating pattern 660 may include silicon nitride, silicon oxynitride, silicon oxide, or a combination thereof. The insulating pattern 660 may be formed of a single layer or multiple layers. For example, the insulating pattern 660 may include a first material layer and a second material layer that are stacked. In this case, the first material layer may include silicon oxide or a low dielectric constant (low-k) material having a low dielectric constant such as SiOCH or SiOC, and the second material layer may include silicon nitride or silicon oxynitride. However, a shape, a material, and the like of the landing pad LP are not limited thereto, and may be variously changed.

Although not shown in the drawings, a capacitor structure may be disposed on the landing pad LP. The capacitor structure may include a first capacitor electrode, a second capacitor electrode, and a dielectric layer disposed between the first capacitor electrode and the second capacitor electrode.

The first capacitor electrode may be in contact with the landing pad LP, and may be electrically connected to the landing pad LP. The capacitor structure may be electrically connected to the active region AR through the landing pad LP and the buried contact BC.

The first capacitor electrode may be disposed on each landing pad LP, and a plurality of first capacitor electrodes may be disposed to be isolated from each other. The same voltage may be applied to second capacitor electrodes of a plurality of capacitor structures, and the second capacitor electrodes of the plurality of capacitor structures may be integrally formed. Dielectric layers of the plurality of capacitor structures may be integrally formed.

Hereinafter, a disposition of the peripheral circuit region A2 will be described. Referring to FIG. 1, the semiconductor device according to the present example embodiment may have different end portions in the first direction DR1 of the word line WL disposed at the peripheral circuit region A2. That is, as shown in FIG. 1, an end portion of one word line from among four word lines that are adjacent to each other in the second direction DR2 on a plane may be disposed closer to the cell array region A1 than an end portion of each of the others of the four word lines.

Referring to a left region of FIG. 1, four word lines adjacent to each other in the second direction DR2 on a plane may constitute one unit UN. In this case, the one unit may include a first word line WL1, a second word line WL2, a third word line WL3, and a fourth word line WL4. As shown in FIG. 1, in the peripheral circuit region A2, a length of the second word line WL2 may be the longest, and a length of the fourth word line WL4 may be the shortest. The length may mean a length in the first direction DR1, and may mean a degree to which one end portion of the word line WL protrudes in the first direction DR1 in the peripheral circuit region A2. That is, a length of the word line WL in the present specification does not mean a length of the word line WL on the entire semiconductor device, but means a length of the word line WL in the first direction DR1 within the peripheral circuit region A2. Therefore, even if the length of the word line WL in the first direction DR1 within the peripheral circuit region A2 is different, a length of the word line WL throughout the peripheral circuit region A2 and the cell array region A1 may be the same.

Referring to FIG. 1, an end portion of the second word line WL2 may be disposed to protrude the most in the first direction DR1, and an end portion of the fourth word line WL4 may be disposed at an innermost side (e.g., located closest to the cell array region A1). In the peripheral circuit region A2, end portions of the first word line WL1 and the third word line WL3 may be disposed between the end portion of the second word line WL2 in the first direction DR1 and the end portion of the fourth word line WL4 in the first direction DR1.

That is, the end portion of the second word line WL2 may be disposed farthest from the cell array region A1 in the first direction DR1, and the end portion of the fourth word line WL4 may be disposed closest to the cell array region A1 in the first direction DR1. The end portion of the first word line WL1 and the end portion of the third word line WL3 may be disposed between the end portion of the second word line WL2 and the end portion of the fourth word line WL4.

A first pad PD1 and a third pad PD3 may be disposed to overlap the first word line WL1 and the third word line WL3, respectively. The first pad PD1 may be in contact with the first word line WL1, and the third pad PD3 may be in contact with the third word line WL3. The first pad PD1 and the third pad PD3 may be disposed to be shifted from a center of the first word line WL1 and the third word line WL3, respectively. In other words, the first pad PD1 overlapping the first word line WL1 may be configured to be shifted in a direction towards the fourth word line WL4 adjacent thereto relative to a center of the first word line WL1, and the third pad PD3 overlapping the third word line WL3 may be configured to be shifted in a direction towards the fourth word line WL4 adjacent thereto relative to a center of the third word line WL3. That is, as shown in FIG. 1, the first pad PD1 disposed to overlap the first word line WL1 may be shifted in the second direction DR2 in a direction away from the third word line WL3 of the same unit UN, and the third pad PD3 disposed to overlap the third word line WL3 may be shifted in the second direction DR2 in a direction away from the first word line WL1 of the same unit UN. That is, the first pad PD1 may be disposed to be shifted in a direction closer to the fourth word line WL4 adjacent to the first pad PD1, and the third pad PD3 may also be disposed to be shifted in a direction closer to the fourth word line WL4 adjacent to the first pad PD3.

Therefore, as shown in FIG. 1, a distance D1 in the second direction DR2 between two pads between which the second word line WL2 is disposed may be different from a distance D2 in the second direction DR2 between two pads between which the fourth word line WL4 is disposed. For example, the distance D1 in the second direction DR2 between two pads between which the second word line WL2 of which an end portion is protruded most in the first direction DR1 is disposed may be longer than the distance D2 in the second direction DR2 between two pads between which the fourth word line WL4 of which an end portion is protruded least in the first direction DR1 is disposed.

That is, in the peripheral circuit region A2, a length in the second direction DR2 between two pads between which the word line with a short length is disposed on a plane may be shorter than a length in the second direction DR2 between two pads between which the word line with a long length is disposed on a plane.

In the present example embodiment, a length of the fourth word line WL4 disposed at the peripheral circuit region A2 may be shorter than a length of another word line, so that a margin capable of shifting the pad PD is secured. That is, the pad PD may be disposed by being shifted to an empty space in which the fourth word line WL4 is not formed. Because the pad PD is disposed by being shifted, a short circuit of the pad may be reduced or prevented and a process margin may be secured compared with a case where the pad PD is correctly (or properly) aligned with the word line WL.

Referring to FIG. 1, the word line that is not connected to the pad PD in a left peripheral circuit region A2 of FIG. 1 may be connected to the pad PD in a right peripheral circuit region A2 of FIG. 1. That is, some word lines WL among the plurality of word lines WL may be connected to the pad PD in the peripheral circuit region A2 disposed at a left side of the cell array region A1, and some word lines WL among the plurality of word lines WL may be connected to the pad PD in the peripheral circuit region A2 disposed at a right side of the cell array region A1.

Referring to a right side of FIG. 1, in the right peripheral circuit region A2, an end portion of the first word line WL1 may be disposed farthest from the cell array region A1, and an end portion of the third word line WL3 may be disposed closest to the cell array region A1. A second pad PD2 and a fourth pad PD4 may be each disposed to overlap the second word line WL2 and the fourth word line WL4, respectively, and each of the pads PD2 and PD4 may be disposed to be shifted in a direction closer to the third word line WL3 that has an end portion protruded least. In other words, the second pad PD2 may be configured to be shifted in a direction towards the third word line WL3 adjacent thereto relative to a center of the second word line WL2, and the fourth pad PD4 may be configured to be shifted in a direction towards the third word line WL3 adjacent thereto relative to a center of the fourth word line WL4. That is, in the right peripheral circuit region A2 of FIG. 1, a distance D3 between two pads between which the first word line WL1 with the longest length is disposed may be longer than a distance D4 between two pads between which the third word line WL3 with the shortest length is disposed.

Hereinafter, an effect and a configuration of the present example embodiment will be described in more detail with reference to the drawings. Each of FIG. 5 and FIG. 6 schematically illustrates a disposition of the word line WL and a disposition of the pad PD at the peripheral circuit region A2. FIG. 5 shows an example in which the plurality of word lines WL have the same length and the pad PD is correctly aligned, and FIG. 6 shows an example in which the plurality of word lines WL have different lengths and the pad PD is shifted.

Referring to FIG. 5, if lengths of all word lines WL are the same, there is no margin for shifting the pad PD. Therefore, a center of each word line WL and a center of the pad PD may be correctly aligned to coincide, and a distance D5 between adjacent pads may be the same throughout the peripheral circuit region A2. In this example, a distance between the pad PD and the word line WL may be narrow, so that a short circuit between the pad PD and the word line WL adjacent to the pad PD occurs during a process.

However, referring to FIG. 6, in the present example embodiment, lengths of the word lines WL in the peripheral circuit region A2 (e.g., in either a left side or a left side of the peripheral circuit region A2) may be implemented to be differently. As shown in FIG. 6, a first word line WL1, a second word line WL2, a third word line WL3, and a fourth word line WL4 may form one unit UN. The unit UN may be repeatedly disposed at the peripheral circuit region. As shown in FIG. 6, in the peripheral circuit region, a length of the second word line WL2 may be the longest, and a length of the fourth word line WL4 may be the shortest. A length of each of the first word line WL1 and the third word line WL3 may be shorter than the length of the second word line WL2, and may be longer than the length of the fourth word line WL4.

A first pad PD1 and a third pad PD3 may be disposed on the first word line WL1 and the third word line WL3. That is, within one unit UN, the pad may not be disposed at the longest word line or the shortest word line, but may be disposed on the word line having an intermediate length. In this case, the pads PD1 and PD3 may be disposed to be shifted in a direction closer to the fourth word line WL4 (e.g., an adjacent fourth word line WL4) that has the shortest length. That is, a center of each of the pads PD1 and PD3 may not coincide with a center of a corresponding one of the word lines WL1 and WL3. Therefore, as shown in FIG. 6, distances D1 and D2 between adjacent pads may be different. The distance D2 between pads between which the fourth word line WL4 with a short length is disposed may be shorter than the distance D1 between pads between which the first word line WL1 with a long length is disposed. The pad PD may be disposed to be shifted in a direction closer to the fourth word line WL4, so that a process margin is secured and a short circuit between the pad PD and the word line WL adjacent to the pad PD is reduced or prevented during a process.

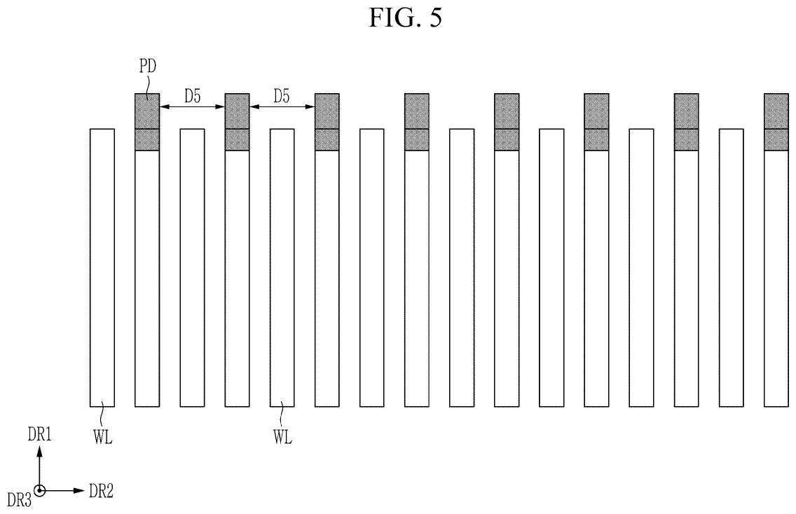

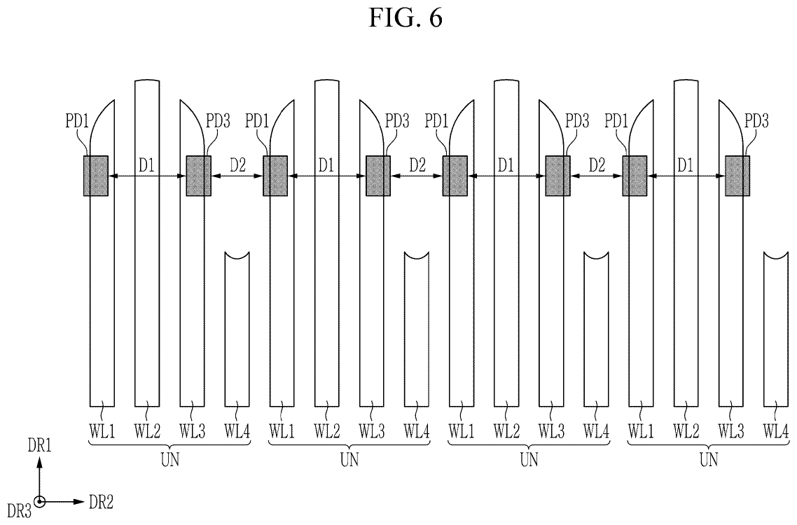

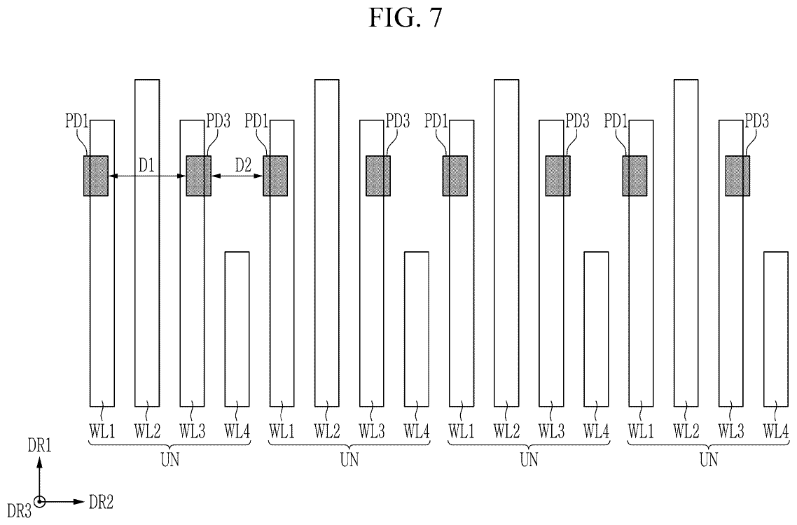

Although an end portion of the word line WL is illustrated as a curved line in FIG. 6, this is only an example, and an end portion of the word line WL may be a straight line. FIG. 7 shows the same region as that of FIG. 6 according to another example embodiment. Referring to FIG. 7, an end portion of the word line WL may have a rod shape that does not include a curved surface.

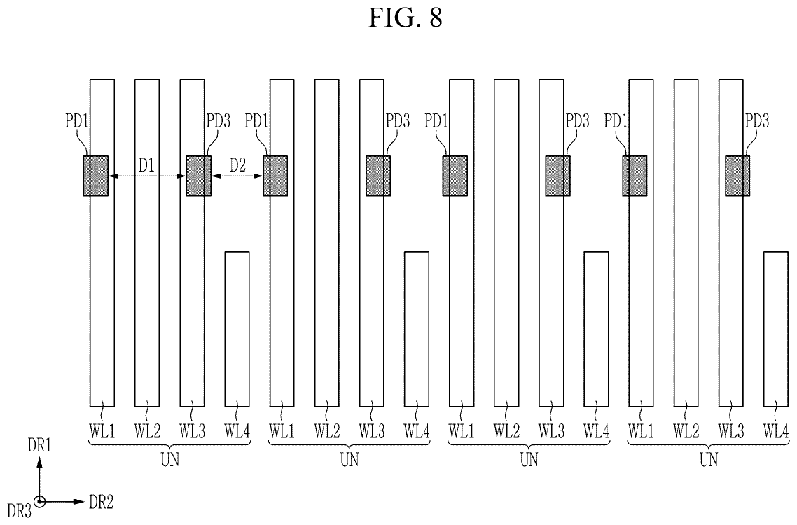

In addition, FIG. 7 illustrates an example embodiment in which a length of a second word line WL2 is the longest and a length of a fourth word line WL4 is the shortest, but this is only an example, and example embodiments of the present disclosure are not limited thereto. FIG. 8 shows the same region as that of FIG. 6 according to another example embodiment. Referring to FIG. 8, a first word line WL1, a second word line WL2, and a third word line WL3 may have the same length, and a fourth word line WL4 may have a relatively short length. In this case, each pad PD1 and PD3 may be disposed to be shifted in a direction closer to the fourth word line WL4 with the shortest length. Therefore, a distance D2 between pads between which the fourth word line WL4 with a relatively short length is disposed may be less than a distance D1 between pads between which the first word line WL1 with a relatively long length is disposed.

Hereinafter, a method for manufacturing the word line according to an example embodiment will be described with reference to the drawings. However, the manufacturing method described below is an example, and example embodiments of the present disclosure are not limited thereto.

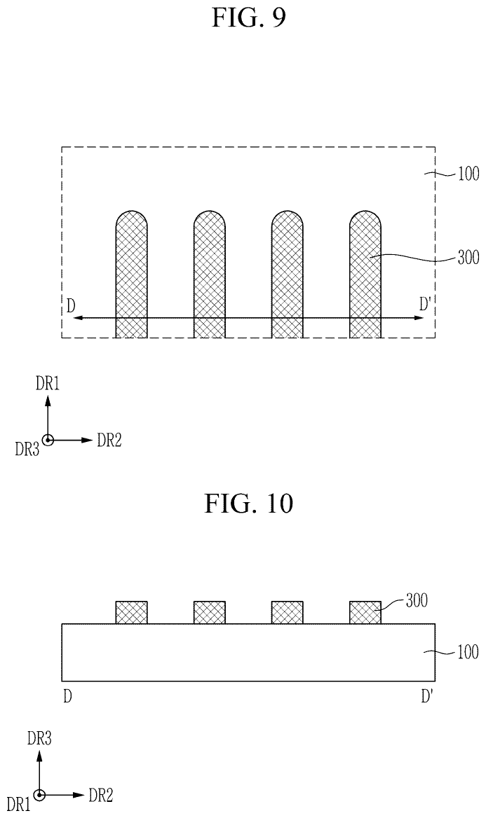

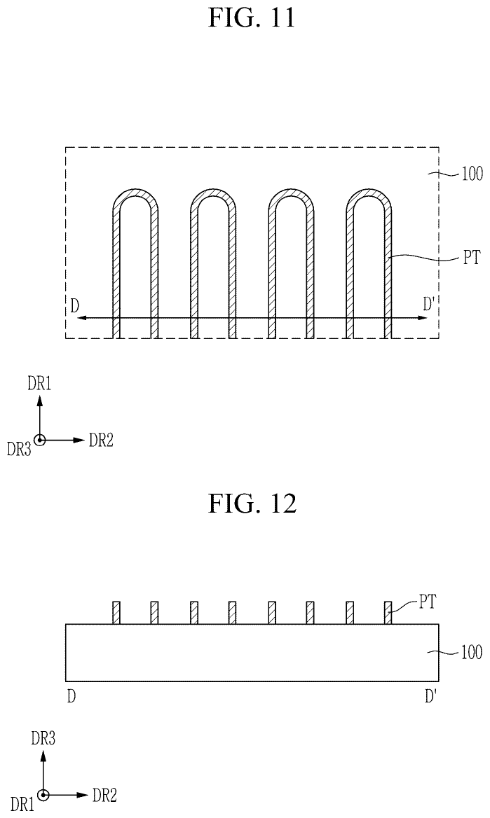

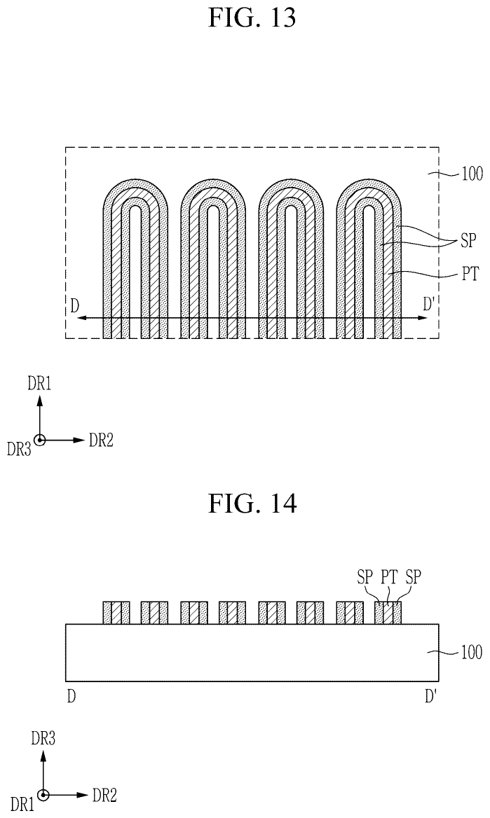

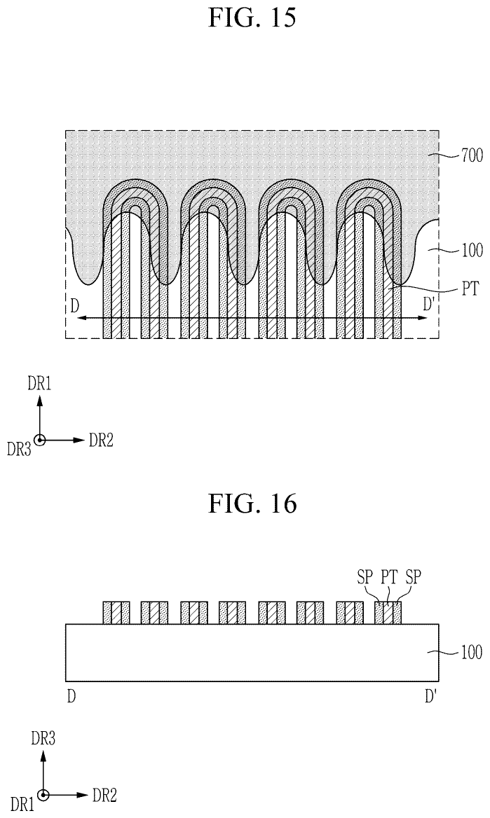

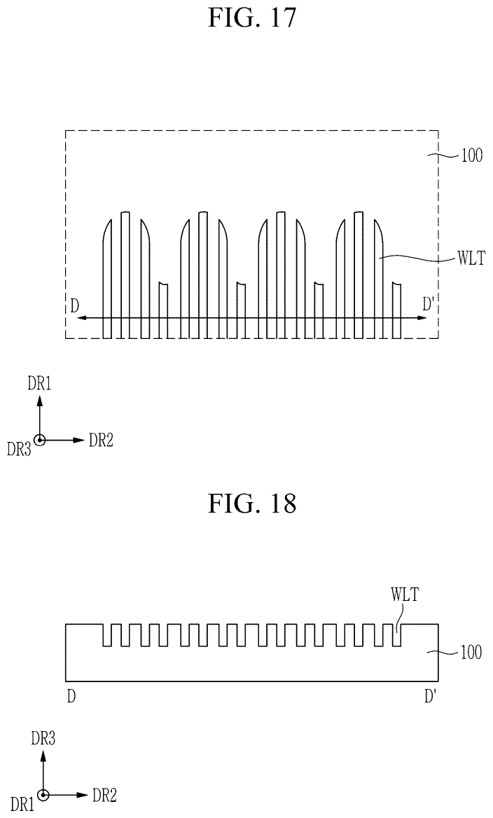

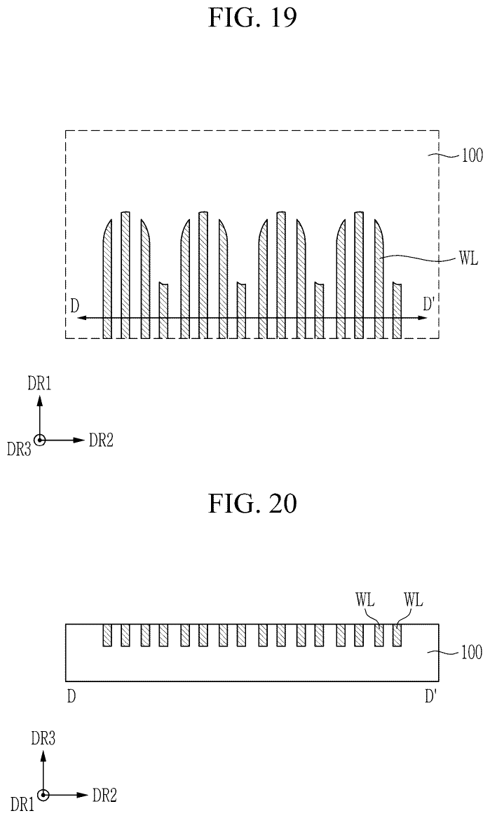

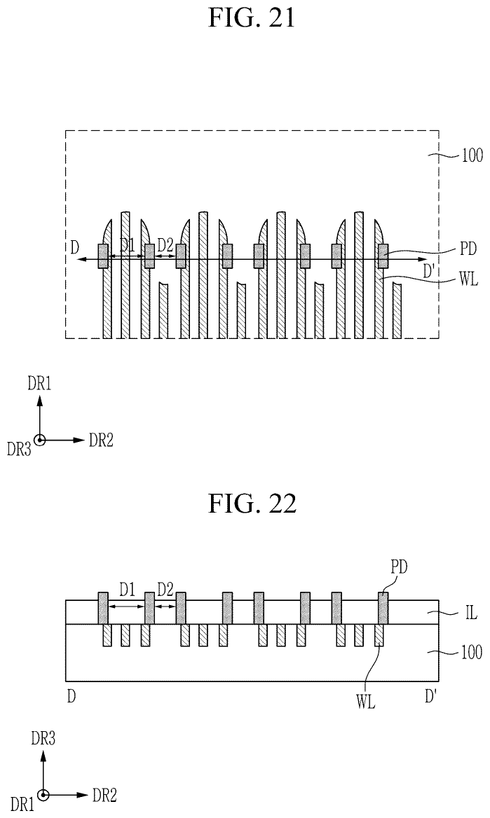

FIGS. 9 to 22 illustrate the manufacturing method according to the embodiment. FIG. 9, FIG. 11, FIG. 13, FIG. 15, FIG. 17, FIG. 19, and FIG. 21 are plan views illustrating a partial region of the peripheral circuit region A2, and FIG. 10, FIG. 12, FIG. 14, FIG. 16, FIG. 18, FIG. 20, and FIG. 22 are cross-sectional views cut along a line D-D′ of FIG. 9, FIG. 11, FIG. 13, FIG. 15, FIG. 17, FIG. 19, and FIG. 21, respectively. For convenience of description, the cross-sectional view briefly shows only the substrate 100, the word line WL, and the pad PD. Although not illustrated in the drawings, various stacking structures shown in FIGS. 2 to 4 may be disposed between the word line WL and the pad PD.

Referring to FIG. 9 and FIG. 10, a dummy pattern 300 may be formed on the substrate 100. The dummy pattern 300 may be formed into a plurality of rod shapes along one direction. Although FIG. 9 illustrates an end portion of the dummy pattern 300 with a curved shape, this is only an example, and example embodiments of the present disclosure are not limited thereto.

Next, referring to FIG. 11 and FIG. 12, a pattern PT may be formed along a circumference of the dummy pattern 300, and the dummy pattern 300 may be removed. The pattern PT may be formed along a side surface of the dummy pattern 300. Therefore, the pattern PT surrounding each dummy pattern 300 may be connected as one.

Next, referring to FIG. 13 and FIG. 14, a spacer SP may be formed along a side surface of the pattern PT. The spacer SP may be formed on both side surfaces of the pattern PT. The spacer SP may be connected to an inner surface and an outer surface of the pattern PT.

Next, referring to FIG. 15 and FIG. 16, edges of the pattern PT and the spacer SP may be isolated. The edge isolation may be performed as a shape shown in FIG. 15. That is, FIG. 15 illustrates that a region of each of the spacer SP and the pattern PT that overlaps the isolation pattern 700 may be removed. In this case, the isolation pattern 700 may have a wave shape on a plane, and one wave of the isolation pattern 700 may overlap four rows of spacers SP. That is, the isolation pattern 700 may include a wave shape with a period that overlaps the four lines of spacers. Therefore, the spacer SP isolated by the isolation pattern 700 may also have an edge of a wave shape that is repeated in four units.

Referring to FIG. 17 and FIG. 18, the pattern PT may be removed, and the substrate 100 in a region where the spacer SP is disposed may be etched to form the word line trench WLT. In this case, a planar shape of the word line trench WLT may be the same as a shape of the spacer SP of the previous step.

Next, referring to FIGS. 19 and 20, the word line WL may be formed within the word line trench WLT. Although a configuration of the word line WL within the word line trench WLT is briefly illustrated in FIG. 19 and FIG. 20, the word line WL may actually have a structure described with reference to FIGS. 1 to 4.

Next, referring to FIG. 21 and FIG. 22, the pad PD may be formed on the word line WL. An insulating film IL may be the pads PD, and the word line WL and the pad PD may be in direct contact with each other through an opening of the insulating film IL. For convenience of description, a cross-section of FIG. 22 briefly illustrates shapes of the word line WL, the insulating film IL, and the pad PD, but example embodiments of the present disclosure are not limited thereto. As illustrated in FIGS. 2 to 4, an actual cross-sectional structure may include various insulating films and various stacking structures included in the cell array region A1.

Referring to FIG. 21 and FIG. 22, as described above, the pad PD may be disposed to be shifted in a direction toward the word line WL with the shortest length. Therefore, as described above, distances D1 and D2 between pads PD may be different from each other.

As described above, in semiconductor devices according to the present example embodiments, end portions of word lines in a peripheral circuit region may be formed not to be aligned with each other, and the pad may be disposed to be shifted in a direction toward a word line that has an end portion protruded the least from a cell array region A1. In other words, an available space secured by the word line with the end portion protruded least may be used as a margin for a disposition of the pad so that a short circuit is reduced or prevented.

It should be understood that example embodiments described herein should be considered in a descriptive sense only and not for purposes of limitation. While some example embodiments have been particularly shown and described, it will be understood by one of ordinary skill in the art that variations in form and detail may be made therein without departing from the spirit and scope of the claims

What is claimed is:

1. A semiconductor device comprising:
a substrate including a cell array region and a peripheral circuit region surrounding the cell array region;
an active region in the cell array region;
a plurality of word lines intersecting and overlapping the active region, the plurality of word lines extending in a first direction to the peripheral circuit region;
a plurality of bit lines intersecting the active region and the plurality of word lines, the plurality of bit lines extending in a second direction intersecting the first direction; and
a plurality of pads in the peripheral circuit region and overlapping corresponding ones of the plurality of word lines, respectively,
wherein in the peripheral circuit region on a first side of the cell array region,
the plurality of word lines include a first word line, a second word line, a third word line, and a fourth word line,
an end portion of at least one of the first word line, the second word line, the third word line, and the fourth word line does not coincide with an end portion of another word line of the first word line, the second word line, the third word line, and the fourth word line,
an end portion of the second word line is farthest from the cell array region and an end portion of the fourth word line is closest to the cell array region, and
from among the plurality of pads, a first pad overlapping the first word line is configured to be shifted in a direction towards the fourth word line adjacent thereto relative to a center of the first word line and a third pad overlapping the third word line is configured to be shifted in a direction towards the fourth word line adjacent thereto relative to a center of the third word line.

2. The semiconductor device of claim 1, wherein a distance in the second direction between the first pad and the third pad, where the fourth word line is located, is less than a distance in the second direction between the first pad and the third pad, where the second word line is located.

3. The semiconductor device of claim 1, wherein the first pad and the third pad do not overlap the fourth word line on a plane.

4. The semiconductor device of claim 1, wherein in the peripheral circuit region, an edge of at least one of the plurality of word lines includes a curved surface.

5. The semiconductor device of claim 1, wherein in the peripheral circuit region, an edge of at least one of the plurality of word lines does not include a curved surface.

6. The semiconductor device of claim 1, wherein an end portion of the first word line and an end portion of the third word line are closer to the cell array region than the end portion of the second word line, and are farther from the cell array region than the end portion of the fourth word line.

7. The semiconductor device of claim 1, wherein end portions of the first word line, the third word line, and the second word line are on a same line in the second direction.

8. The semiconductor device of claim 1, wherein from among the plurality of pads, a second pad overlapping the second word line and a fourth pad overlapping the fourth word line are in the peripheral circuit region on a second side of the cell array region, the second side of the cell array region being opposite to the first side of the cell array region.

9. The semiconductor device of claim 8, wherein in the peripheral circuit region on the second side of the cell array region,
an end portion of the third word line is closest to the cell array region in the first direction,
the second pad is configured to be shifted in a direction towards the third word line adjacent thereto relative to a center of the second word line, and
the fourth pad is shifted in a direction towards the third word line adjacent thereto relative to a center of the fourth word line.

10. The semiconductor device of claim 9, wherein a distance in the second direction between the second pad and the fourth pad between, where the third word line is located, is less than a distance in the second direction between the second pad and the fourth pad, where the first word line is located.

11. A semiconductor device comprising:
a substrate including a cell array region and a peripheral circuit region surrounding the cell array region;
an active region in the cell array region;
a plurality of word lines intersecting and overlapping the active region, the plurality of word lines extending in a first direction to the peripheral circuit region;
a plurality of bit lines intersecting the active region and the plurality of word lines, the plurality of bit lines extending in a second direction intersecting the first direction; and
a plurality of pads in the peripheral circuit region and overlapping corresponding ones of the plurality of word lines,
wherein end portions of two or more of the plurality of word lines in the peripheral circuit region protrude in the first direction to different degrees, and
distances in the second direction between adjacent pairs of the plurality of pads in the peripheral circuit region are different.

12. The semiconductor device of claim 11, wherein a distance in the second direction between a first adjacent pair of the plurality of pads, where a first word line, from among the plurality of word lines, of which an end portion is closest to the cell array region is located, is less than a distance in the second direction between a second adjacent pair of the plurality of pads, where a second word line, from among the plurality of word lines, of which an end portion is farthest from the cell array region is located.

13. The semiconductor device of claim 11, wherein each of the plurality of pads is shifted in a direction towards an adjacent word line, from among the plurality of word lines, of which an end portion is closest to the cell array region.

14. The semiconductor device of claim 11, wherein a center of each of the plurality of word lines does not coincide with a center of a corresponding one of the plurality of pads.

15. The semiconductor device of claim 11, wherein the plurality of pads are at of the plurality of word lines, respectively, except for a word line of which an end portion is farthest in the first direction and a word line of which an end portion is closest to the cell array region in the first direction among the plurality of word lines in the peripheral circuit region.

16. A semiconductor device comprising:
a substrate including a cell array region and a peripheral circuit region surrounding the cell array region;
an active region in the cell array region;
a plurality of word lines intersecting and overlapping the active region, the plurality of word lines extending in a first direction to the peripheral circuit region;
a plurality of bit lines intersecting the active region and the plurality of word lines, the plurality of bit lines extending in a second direction intersecting the first direction; and
a plurality of pads in the peripheral circuit region and overlapping corresponding ones of the plurality of word lines,
wherein end portions of two or more of the plurality of word lines in the peripheral circuit region protrude in the first direction to different degrees, and
a center of a word line of the plurality of word lines does not coincide with a center of a pad of the plurality of pads overlapping the word line.

17. The semiconductor device of claim 16, wherein
the plurality of word lines include a first word line, a second word line, a third word line, and a fourth word line that are arranged along the second direction, and
an end portion of the second word line is farthest from the cell array region and an end portion of the fourth word line is closest to the cell array region.

18. The semiconductor device of claim 17, wherein
the plurality of pads includes a first pad overlapping the first word line and a third pad overlapping the third word line, and
a distance in the second direction between the first pad and the third pad, where the fourth word line is located, is less than a distance in the second direction between the first pad and the third pad, where the second word line is located.

19. The semiconductor device of claim 18, wherein the first pad and the third pad do not overlap the fourth word line on a plane.

20. The semiconductor device of claim 16, wherein in the peripheral circuit region, an edge of at least one of the plurality of word lines includes a curved surface.
